(19) United States
(12) Patent Application Publication
(10) Pub. No.: US 2025/0348281 A1
(43) Pub. Date: Nov. 13, 2025

(54) ANALOG RANDOM SEQUENCE GENERATORS

(71) Applicant: NVIDIA Corp., Santa Clara, CA (US)

(72) Inventors: Sanquan Song, Los Altos Hills, CA (US); Mahmut Ersin Sinangil, Los Altos, CA (US); Sudhir Shrikantha Kudva, Dublin, CA (US); Nikola Nedovic, San Jose, CA (US); Satish Anand, San Diego, CA (US)

(73) Assignee: NVIDIA Corp., Santa Clara, CA (US)

(21) Appl. No.: 18/657,039

(22) Filed: May 7, 2024

(51) Int. Cl. G06F 7/58; H03K 3/03

(52) U.S. Cl. CPC G06F 7/588; H03K 3/0315

(57) ABSTRACT

Random sequence generators utilizing one or more noise generators that include an inverter chain with at least one input stage inverter configured with resistive feedback and additional inverters configured in series with the at least one input stage inverter, wherein an output of the inverter chain is coupled to a bit sequence generator.

### BACKGROUND

The generation of random bit sequences is essential for the security of complex electronic systems, such as graphics processing units (GPUs) and central processing units (CPUs), to guard against hacking. If certain sequences or codes utilized internally by these devices is not sufficiently random, a hacker may collect the statistical information about the internal operation and increase the probability of successfully hacking the devices.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts a conventional random sequence generator based on ring oscillators.

FIG. 2A-FIG. 2D depict noise generators in various embodiments.

FIG. 3 depicts a noise generator utilizing differential elements in one embodiment.

FIG. 4A-FIG. 4D depict noise generators applied to ring oscillator-based random sequence generators in various embodiments.

FIG. 5A-FIG. 5B depict noise generators applied to sense amplifier-based random sequence generators in various embodiments.

### DETAILED DESCRIPTION

Disclosed herein are analog mechanisms for generating random sequences. A noise source comprising an inverter with restive feedback generates random thermal noise that is applied to one or more ring oscillators or sense amplifiers to generate random sequences in various implementations.

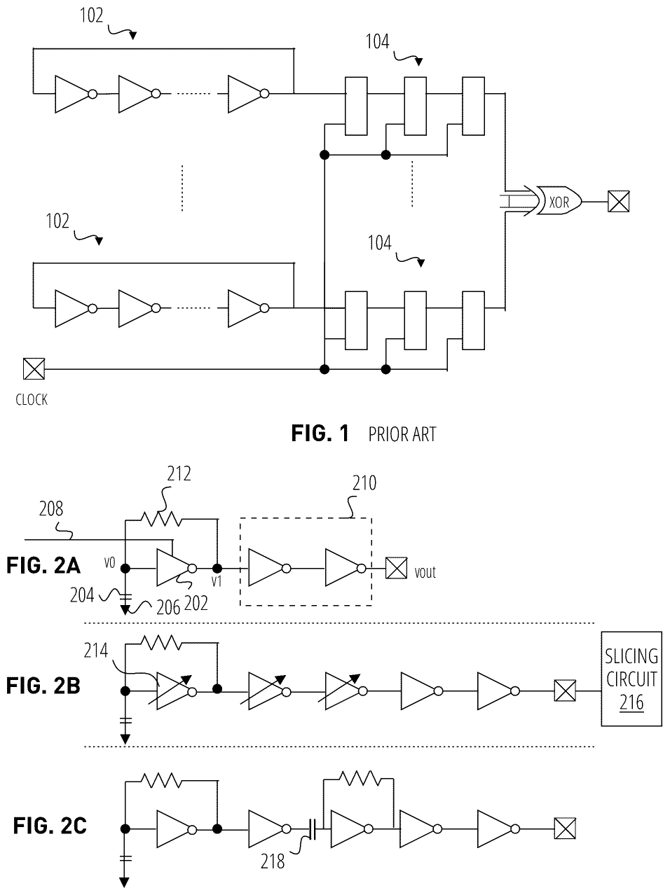

FIG. 1 depicts a conventional random sequence generator based on ring oscillators.

In the depicted example, a plurality of ring oscillators 102 each comprising a different number of inverter stages are sampled by latches 104 responsive to a reference clock, and the sampled values are input to XOR logic to generate a randomized bit sequence. The output randomness may be sufficient if the number of ring oscillators 102 utilized is large enough. This structure comprises two main sources of noise: supply voltage/current noise, and noise from the logic utilized in the ring oscillators 102, which is primarily thermal noise. The supply noise is usually bounded while the device thermal noise has a Gaussian characteristic. Both sources cause random phase drift between the ring oscillator outputs and sampling clock. This mechanism may exhibit a large entropy difference between model predictions and lab measurements of randomness.

The XOR logic preserves and combines the randomness from the multiple ring oscillators 102. It is however challenging to model the entropy transfer function when the XOR logic combines two or more randomizing sources whereby multiple binary distributed random variables are mixed.

In one aspect, randomness of the generated numbers may be improved by enhancing noise sources prior to applying the noise to later stages such as ring oscillators.

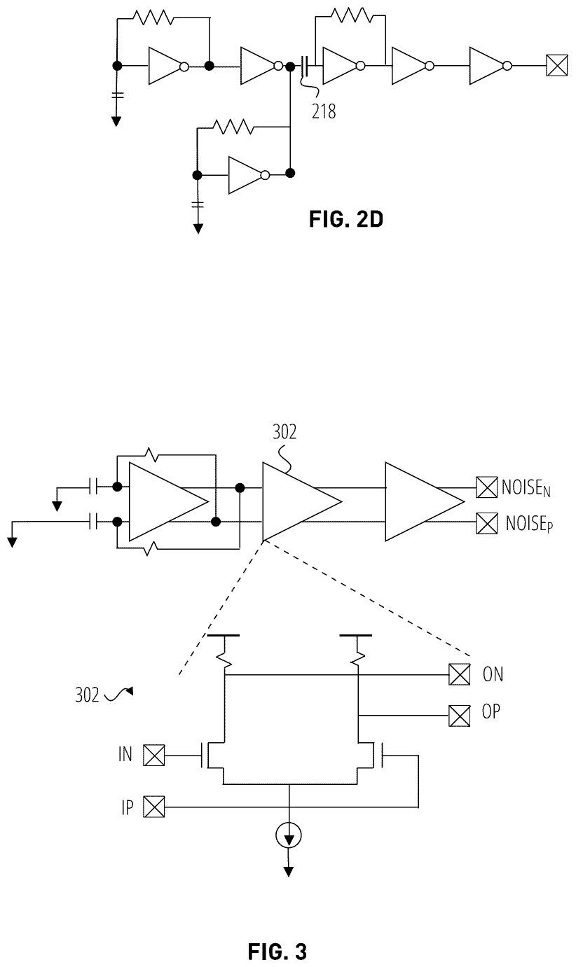

FIG. 2A depicts a noise generator in one embodiment. The depicted embodiment comprises an inverter 202 and a shunt capacitor 204. In alternative implementations, the shunt capacitor 204 may not be utilized, or shunt capacitors may be utilized to both of the circuit ground node 206 and the circuit supply node 208. Although not depicted in all drawings, the supply node 208 may be understood to provide power to at least the noise input stage inverters depicted therein.

The shunt capacitor 204 in the embodiment of FIG. 2A grounds the input to the input stage inverter 202. Although the input stage in the depicted embodiment comprises a single inverter with resistive feedback, more generally the input stage may comprise multiple inverters, each or some comprising resistive feedback.

The input stage of the random sequence generator is followed by (one or more) additional inverter stages 210 for additional noise amplification, thereby forming an inverter chain. Due to the feedback through the resistive element 212, providing a bias voltage for the inverter stages 210 with a maximum small signal gain.

The thermal noise from the inverter 202 and the feedback resistive element 212 generate a voltage disturbance on v/that is further amplified by the later inverter stages 210. More inverter stages may be inserted to generate a higher voltage noise amplitude as called for by the particular implementation.

In the embodiment depicted in FIG. 2B, the PN ratio (size ratio of the PFET and NFET devices) of tunable inverters 214 may be configured to match the switching voltage of said tunable inverter 214 to improve the gain and balance at the output vout. To calibrate the PN ratio, a slicing circuit 216 may be operated on vout and the tunable inverter 214 tuned until the slicing circuit 216 output is 0/1 balanced. Alternatively or additionally, as depicted in the embodiment of FIG. 2C, a capacitor 218 may be inserted in series with the inverters to block DC components of the signal to improve robustness in the presence of switching voltage mismatches. Also as depicted in FIG. 2C, multiple noise input stages may be utilized in the inverter chain. FIG. 2D depicts another embodiment utilizing a shunt capacitor and multiple input stage noise sources.

Due to the high gain from v0/v1 to vout, the circuits depicted in FIG. 2A-FIG. 2C may be sensitive to noise sources such as supply noise. For the first-stage inverter 202, the input signal experiences a gain of gₘₙ+gₘₚ (where gun is the transconductance of the NMOS transistors in the inverter 202 and gₘₚ is the transconductance of the PMOS transistors in the inverter 202). The supply noise experiences a gain of gₘₚ (assuming an input to the inverter 202 with zero capacitive coupling to the supply node). The gain ratio of the two paths (signal path from v0 to v1 and supply noise path from inverter 202 to v1) is approximately (gₘₙ+gₘₚ)/gₘₚ. Though the gain from the input is greater, the thermal noise signal itself may be small compared with the supply noise for the first several inverter stages. In some embodiments, it may be beneficial to configure vout at rail-to-rail so that the thermal noise is not overwhelmed by the supply noise. Alternatively, the input capacitance c to the first-stage inverter 202, and other parasitic capacitances, may be configured to be approximately 50% coupled to ground and 50% coupled to supply voltage, reducing the supply noise gain and maintaining the thermal noise as the dominant factor influencing the output vout. In these manners, supply noise may be suppressed or enhanced relative to thermal noise, according to the needs of particular implementations.

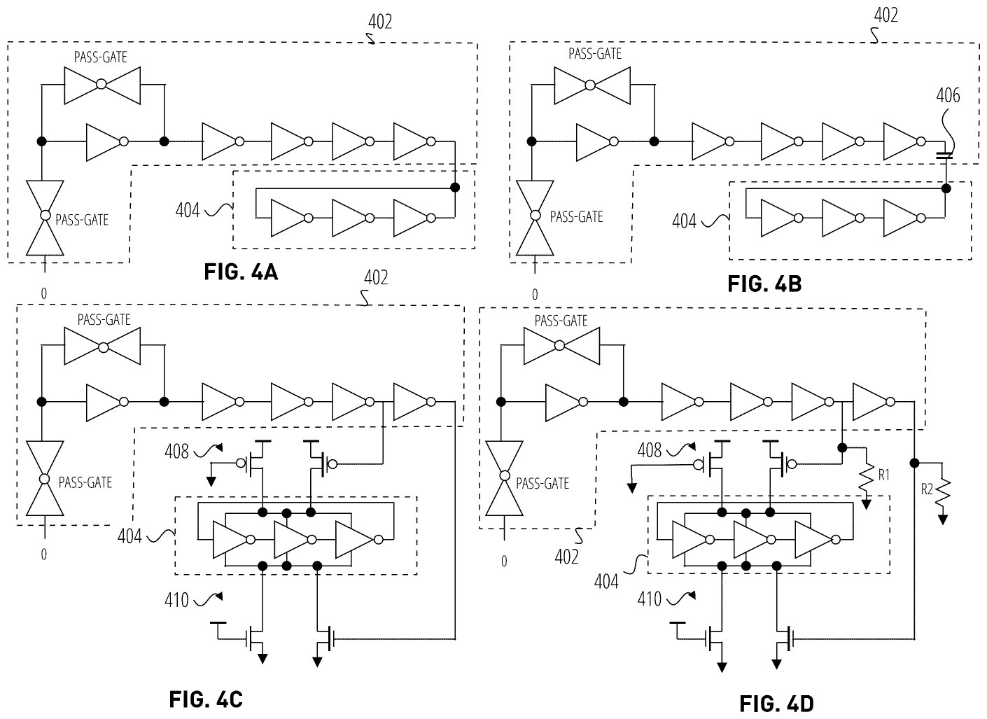

Embodiments of the noise generators depicted in FIG. 2A-FIG. 2C, and in other figures herein, may be implemented to generate differential outputs, for example using differential inverters 302 as depicted in FIG. 3.

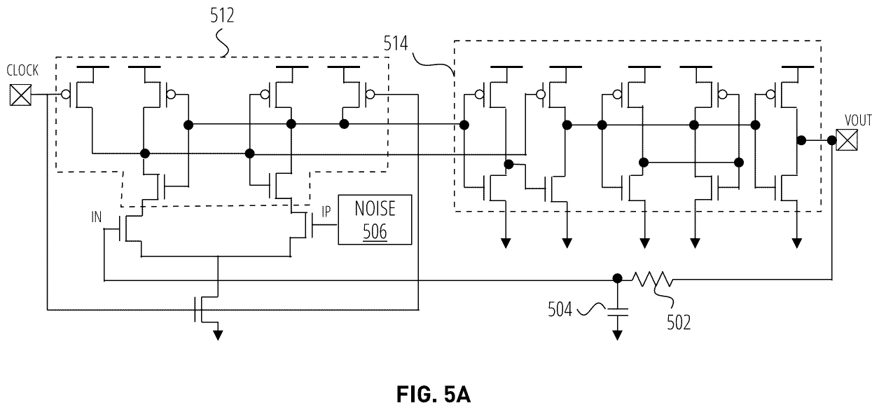

FIG. 4A-FIG. 4D depict noise generators 402 applied to ring oscillator-based random sequence generators. The noise generators 402 boost jitter in the ring oscillators 404 and thereby improve the entropy of the generated random sequences. In the embodiment depicted FIG. 4A, the noise generator 402 couples directly to a node of the ring oscillator 404 structure, thereby coupling both the DC and AC noise into the ring oscillator 404. In this embodiment, the ring oscillator 404 output should be configured to dominate the last stage of the noise generator 402 to help ensure oscillation.

In the embodiment of FIG. 4B, a capacitor 406 is disposed between the noise generator 402 and the ring oscillator 404 to enable the AC noise to pass through while filtering out DC components, thereby enabling the oscillation by design.

In the embodiments depicted in FIG. 4C and FIG. 4D, output of the noise generator 402 is coupled into the ring oscillator 404 via the header 408 and footer 410 transistors of the ring oscillator 404. Utilization of bleeders (e.g., one or both of resistive elements R1 and R2) may help ensure oscillation of the ring.

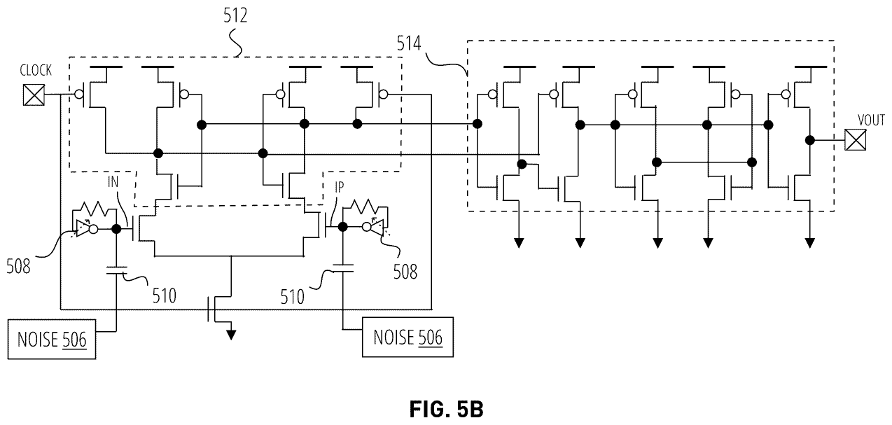

FIG. 5A depicts an embodiment of a random sequence generator utilizing a sense amplifier. The random sequence generator comprises a low pass filter (resistive element 502 and capacitor 504) in a feedback path from the output vout to a noise input IN so that the output is 0/1 balanced in an analog capacity. Unlike some conventional designs, the embodiment in FIG. 5A need not be periodically recalibrated to account for drift induced by voltage and/or temperature variations, and does not utilize complicated calibration mechanisms such as a digital finite state machine.

In one embodiment, the amplitude of the injected noise from the noise generator 506 may be configured during an initial calibration (e.g., calibrating inverters 508) to minimize (reduce to an acceptable threshold) the entropy loss from the sense amplifier's input offset. In some implementations the random sequence generator's entropy may be configured using an initial calibration, and the analog feedback may be enabled during operation to maintain the entropy at an appropriate level.

To help ensure high entropy of the generated random sequences, the correlation between pairs of sequential outputs should be sufficiently low. In the frequency domain, the spectrum of the noise generators 506 should take a form in which the aliased spectrum after sampling is flat such that the generated bit stream at vout takes on the spectrum of white noise. Each inverter of the noise generators 506 contributes a pole at its output such that the low frequency component of the noise signal exceeds the high frequency component in amplitude. This may introduce correlation among the generated random sequence bits.

One mechanism to address this issue is to lower the clock (CLOCK) frequency so that aliasing effects flatten the frequency spectrum of the generated noise. However, this reduces the throughput of the random sequence generator. To reduce correlation while maintaining output bandwidth, coupling capacitors 510 may be disposed between the noise generators 506 and inputs IN and IP to sense amplifier 512 as depicted in the embodiment of FIG. 5B. The capacitors 510 block the DC component of the noise signals such as the spectrum after aliasing is flatter.

With conventional ring oscillator-based mechanisms, power supply injected noise increases the randomness of the output. However in a sense amplifier based mechanism, the transfer function from the power supply noise to the inputs IN and IP may actually reduce the entropy (randomness) of the generated bit sequence. Therefore, lowering the influence of the supply noise at IN and IP on the outputs, via matching, may be desired. Embodiments in accordance with FIG. 5B may match the responses to the supply noise automatically and maintain high entropy of the signals at the sampling latches 514 and output vout.

### LISTING OF DRAWING ELEMENTS

102 ring oscillator
104 latches
202 inverter
204 shunt capacitor
206 ground node
208 supply node
210 inverter stages
212 resistive element
214 tunable inverter
216 slicing circuit
218 capacitor
302 differential inverter
402 noise generator
404 ring oscillator
406 capacitor
408 header
410 footer
502 resistive element
504 capacitor
506 noise generator
508 calibrating inverter
510 capacitor
512 sense amplifier
514 latches

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation-[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112 (f) for that claim element. Accordingly, claims in this application that do not otherwise include the “means for” [performing a function] construct should not be interpreted under 35 U.S.C § 112 (f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. A random sequence generator comprising:
an inverter chain comprising:
at least one input stage inverter configured with resistive feedback;
a plurality of additional inverters configured in series with the at least one input stage inverter; and
an output of the series of additional inverters coupled to a bit sequence generator.

2. The random sequence generator of claim 1, wherein the bit sequence generator comprises at least one ring oscillator.

3. The random sequence generator of claim 1, wherein the bit sequence generator comprises at least one sense amplifier.

4. The random sequence generator of claim 3, further comprising:
a low-pass filtering feedback loop configured to compensate for an offset of the at least one sense amplifier.

5. The random sequence generator of claim 3, further comprising:
an AC coupling configured to reduce correlation between bits generated by the sense amplifier.

6. The random sequence generator of claim 1, further configured with logic to suppress or enhance supply noise relative to thermal noise generated in the series of additional inverters.

7. The random sequence generator of claim 1, wherein the output of the series of additional inverters is coupled to the bit sequence generator via an AC coupling capacitor.

8. The random sequence generator of claim 1, wherein the series of additional inverters comprises differential inverters.

9. The random sequence generator of claim 1, wherein an input of the input stage inverter is shunted via a capacitor to ground.

10. The random sequence generator of claim 1, wherein a ratio of input voltage and output voltage of the input stage inverter is configured to be approximately ½ of a supply voltage level applied to the random sequence generator.

11. The random sequence generator of claim 1, wherein one or more inverters of the series of additional inverters is configured to have a tunable PN ratio.

12. The random sequence generator of claim 11, wherein the PN ratio is configured to match a switching voltage of the one or more inverters.

13. The random sequence generator of claim 1, further comprising a slicing circuit configured at an output of the series of additional inverters.

14. The random sequence generator of claim 1, further comprising a DC-filtering capacitor arranged along the series of additional inverters.

15. The random sequence generator of claim 1, wherein at least one inverter of the additional inverters is configured with resistive feedback.

16. The random sequence generator of claim 1, wherein the output of the series of additional inverters is coupled to the bit sequence generator via one or both of a header of the bit sequence generator and a footer of the bit sequence generator.

17. The random sequence generator of claim 16, further configured with bleeders on one or both of the coupling between the series of additional inverters and the header or the footer.

18. A random bit sequence generator comprising:
at least one noise source comprising an inverter with resistive feedback configured to receive a power supply voltage;
an output of the at least one noise source coupled as an input to an inverter chain;
an output of the inverter chain coupled as an input to a bit sequence generator; and
the at least one noise source configured to enhance thermal noise effects over supply noise effects at the input to the inverter chain.

19. The random bit sequence generator of claim 18, the bit sequence generator comprising a ring oscillator.

20. The random bit sequence generator of claim 18, the bit sequence generator comprising a sense amplifier.
